(19) United States
(12) Patent Application Publication
(10) Pub. No.: US 2010/0149806 A1
(43) Pub. Date: Jun. 17, 2010

(54) LED LIGHTING DEVICE AND METHOD OF MANUFACTURING THE SAME

(76) Inventor: Chi To Yiu, Hong Kong (HK)

Correspondence Address: BYIP, LTD., P.O. BOX 1484, GENERAL POST OFFICE, HONG KONG, HK

(21) Appl. No.: 12/399,045

(22) Filed: Mar. 6, 2009

(30) Foreign Application Priority Data
Dec. 15, 2008 (CN) 200810241212.3

(51) Int. Cl. F21V 21/00; H01L 21/56

(52) U.S. Cl. 362/249.02; 438/28; 257/E21.502; 257/E33.059

(57) ABSTRACT

A light emitting diode (LED) lighting unit is provided. The LED lighting unit includes a printed circuit board having pairs of electrical terminals formed on one side thereof, a casing integrally formed on the one side of the printed circuit board by injection molding, and a plurality of LED chips. Each of the LED chips is electrically connected to each pair of electrical terminals, and the LED chips are exposed in the casing. The printed circuit board may be provided with a plurality of apertures for receiving molding material of the casing during injection molding. A method of manufacturing the LED lighting unit is also provided.

### CROSS-REFERENCE TO RELATED PATENT APPLICATIONS

This patent application claims priority of Chinese patent application no. 200810241212.3 filed on Dec. 15, 2008, the entire contents of which are hereby incorporated by reference.

### FIELD OF PATENT APPLICATION

The present application relates generally to a light emitting diode (LED) lighting device and a method of manufacturing the same, and particularly to a printed circuit board integrally formed with a casing for direct mounted of LED chips thereon.

### BACKGROUND

Technology development makes light emitting diode (LED) lighting devices more and more popular in offices, malls, homes, roads and traffic lights. However, the conventional LED lighting devices are formed by sealing LEDs in individual surface-mount-device (SMD) type or lead frame-type LED packages, and then attaching these individual LED packages onto a printed circuit board. These conventional LED lighting devices are complicated to manufacture, high in manufacturing costs, and poor in heat dissipation. These disadvantages limit the application of these LED lighting devices.

The above description of the background is provided to aid in understanding the LED lighting device and method disclosed in the present application, but is not admitted to describe or constitute pertinent prior art to the LED lighting device and method, or consider any cited documents as material to the patentability of the claims of the present application.

### SUMMARY

In one aspect, a light emitting diode (LED) lighting unit is provided. The LED lighting unit includes a printed circuit board having pairs of electrical terminals formed on one side thereof, a casing integrally formed on the one side of the printed circuit board by injection molding, and a plurality of LED chips. Each of the LED chips is electrically connected to each pair of electrical terminals, and the LED chips are exposed in the casing.

In one embodiment, the casing is in the form of an overlaying panel having a plurality of openings each exposing one pair of the electrical terminals, and defining a plurality of cavities for receiving the LED chips. A light transmissible sealing material is used to fill in each cavity encapsulating each LED chip in each cavity. Each cavity may have an outwardly diverging wall in generally truncated conical shape to facilitate LED light emission. The outwardly diverging wall in cross section may have an angle in cross section between 0° and 180° with respect to a surface of said one side of said printed circuit board.

In another embodiment, the casing is in the form of an overlaying panel having one opening that exposes the pairs of electrical terminals on the printed circuit board.

The first and second electrical contacts of each of the LED chips are connected to first and second electrical terminals of a corresponding pair of electrical terminals, respectively. The first electrical contact may be connected to the first electrical terminal by an electrical wire. The second electrical contact may be connected to the second electrical terminal by an adhesive conductive material.

The printed circuit board is provided with a plurality of apertures for receiving molding material of the casing during injection molding.

In another aspect, a lighting device having one or more light emitting diode (LED) lighting units is provided. Each of the LED lighting units includes a printed circuit board having pairs of electrical terminals formed on one side thereof, a casing integrally formed on the one side of the printed circuit board by injection molding, and a plurality of LED chips. The printed circuit board is provided with a plurality of apertures for receiving molding material of the casing during injection molding. Each of the LED chips is electrically connected to each pair of electrical terminals. The the LED chips are exposed in the casing. The casing is in the form of an overlaying panel having a plurality of openings each exposing one pair of the electrical terminals, and defining a plurality of cavities for receiving the LED chips. Each of the LED lighting units also includes a light transmissible sealing material filled in each cavity encapsulating each of the LED chips in each of the cavities.

The lighting device may include one or more conductive connectors connecting the LED lighting units in an end-to-end configuration if there are two or more LED lighting units.

The lighting device may include an elongated tube for receiving therein the LED lighting units, and a pair of electrode plug heads secured to two opposite ends of the elongated tube.

In another aspect, a method of manufacturing a light emitting diode (LED) lighting unit includes the steps of: providing a printed circuit board with pairs of electrical terminals formed on one side thereof, integrally forming a casing on the one side of the printed circuit board by injection molding while exposing the pairs of electrical terminals, providing a plurality of LED chips, and electrically connecting each of the LED chips to each pair of electrical terminals.

The printed circuit board is provided with a plurality of apertures for receiving molding material of the casing during injection molding.

In one embodiment, the casing is in the form of an overlaying panel having a plurality of openings each exposing one pair of the pairs of electrical terminals, and defining a plurality of cavities for receiving the LED chips. The method of manufacturing the LED lighting unit may further include filling each cavity with a light transmissible sealing material that encapsulates each LED chip in each cavity after the step of electrically connecting each of the LED chips to each pair of electrical terminals.

The step of electrically connecting each of the LED chips to each pair of electrical terminals may include connecting first and second electrical contacts of each of the LED chips to first and second electrical terminals of a corresponding pair of electrical terminals, respectively.

### BRIEF DESCRIPTION OF THE DRAWINGS

Specific embodiments of the LED lighting device and method disclosed in the present application will now be described by way of example with reference to the accompanying drawings wherein:

FIG. 1(a) is a perspective view of a LED lighting unit according to an embodiment disclosed in the present patent application;

FIG. 1(b) is an enlarged view of a cavity of the LED lighting unit in FIG. 1(a);

FIG. 1(c) is a cross sectional view of a cavity of the LED lighting unit taken along the line A-A in FIG. 1(a);

FIG. 2(a) is a perspective view of a printed circuit board of the LED lighting unit of FIG. 1(A);

FIG. 2(b) is an enlarged view of a circuit of the printed circuit board in FIG. 2(a);

FIG. 3 is a perspective view showing a casing integrally formed on the printed circuit board in FIG. 2(a);

FIG. 4 is a perspective view showing LED chips secured in cavities defined by the casing and the printed circuit board;

FIG. 5 is a perspective view showing cavities covered by a light transmissible sealing material;

FIG. 6 is a perspective view of a LED lighting unit according to another embodiment disclosed in the present application;

FIG. 7(a) is an illustrative diagram illustrating the manufacturing process of placing a printed circuit board in a lower mold;

FIG. 7(b) is an illustrative diagram illustrating the manufacturing process of placing an upper mold on the lower mold, injecting molding material from the upper mold;

FIG. 7(c) is an illustrative diagram illustrating the manufacturing process of removing the molded product after injection molding;

FIG. 8(a) illustrates the manufacturing of the LED lighting unit according to another embodiment disclosed in the present application;

FIG. 8(b) is an enlarged view of a cavity of the LED lighting unit in FIG. 8(a);

FIG. 9 is a perspective view showing the connection of a plurality of LED lighting units shown in FIG. 8(a); and

FIG. 10 depicts the assembling of a lighting device using the plurality of LED lighting units in FIG. 9.

### DETAILED DESCRIPTION

Reference will now be made in detail to a preferred embodiment of the LED lighting device and method disclosed in the present application, examples of which are also provided in the following description. Exemplary embodiments of the LED lighting device and method disclosed in the present application are described in detail, although it will be apparent to those skilled in the relevant art that some features that are not particularly important to an understanding of the LED lighting device and method may not be shown for the sake of clarity.

Furthermore, it should be understood that the LED lighting device and method disclosed in the present application are not limited to the precise embodiments described below and that various changes and modifications thereof may be effected by one skilled in the art without departing from the spirit or scope of the appended claims. For example, elements and/or features of different illustrative embodiments may be combined with each other and/or substituted for each other within the scope of this disclosure and appended claims.

It should be noted that throughout the specification and claims herein, when one element is said to be “connected” to another, this does not necessarily mean that one element is fastened, secured, or otherwise attached to another element. Instead, the term “connected” means that one element is either connected directly or indirectly to another element, or is in mechanical and/or electrical communication with another element.

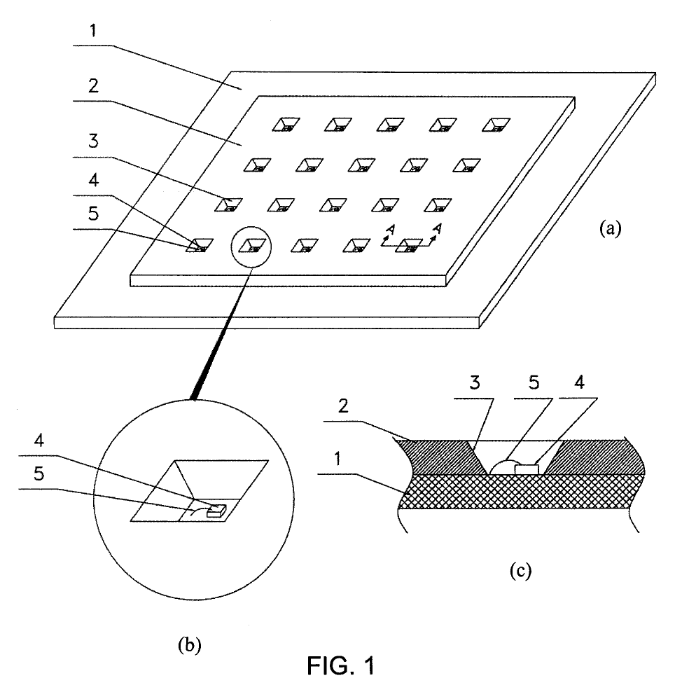

Referring now to the drawings, in which like reference numerals represent like parts throughout the drawings, FIG. 1(a) is a perspective view of a light emitting diode (LED) lighting unit according to an embodiment disclosed in the present patent application.

The LED lighting unit includes a printed circuit board (PCB) 1, a casing 2 integrally formed on one side of the PCB 1, a plurality of openings 3 provided on the casing 2, a LED chip 4 deposited in each opening 3, and an electrical wire 5 for electrical connecting the LED chip 4 to the PCB 1.

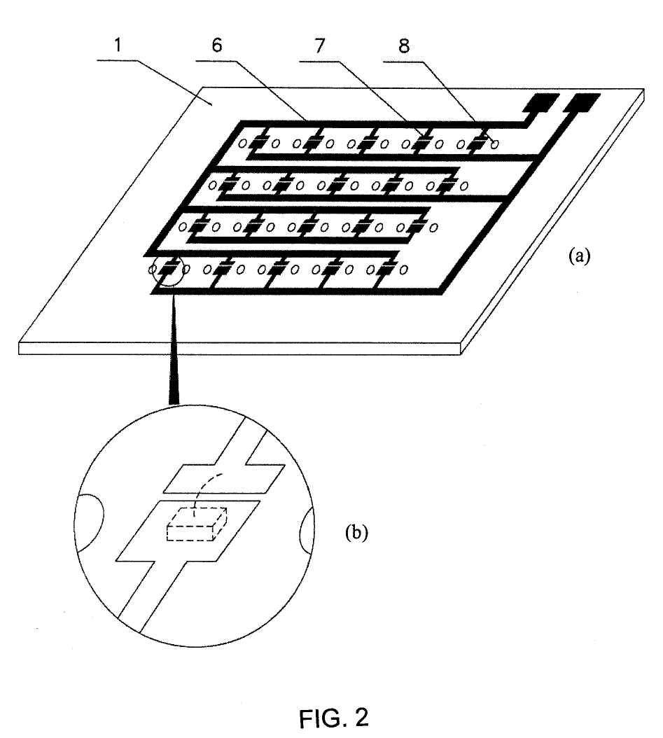

The PCB 1 can take the form of a rigid or flexible substrate or board. The PCB 1 can be conventionally rectangular in shape, as shown in the illustrated embodiment in FIG. 2(a), or in any other shapes such as circle or polygonal. The PCB 1 may be made of an insulating material. Alternately, the board may be made of a conductive metallic material, which may be suitable for the dissipation of heat generated from the LED chips 4. A pattern of electrical conductors 6 can be formed on the substrate or board of the PCB 1 on one side thereof. The pattern of electrical conductors 6 includes pairs of electrical terminals 7 for electrical connection with the LED chips 4.

According to one embodiment disclosed in FIG. 1(a), the casing 2 can be in the form of an overlaying panel having a plurality of square openings 3 formed thereon. Each opening 3 may expose one pair of electrical terminals 7 formed on one side the PCB 1. The plurality of openings 3 defines a plurality of cavities for receiving a plurality of LED chips 4 therein respectively. The plurality of openings 3 can be arranged in any pattern depending on the design of the final lighting device to be formed. According to the illustrated embodiment, the plurality of openings 3 may be arranged in an array of four rows and five columns.

The casing 2 may be made of a white-colored moldable plastic material, which has a high reflection rate and a high deformation temperature. The casing 2 can be formed on one side of the PCB 1 by injection molding using a conventional injection molding machine.

FIG. 1(b) is an enlarged view of a cavity of the LED lighting unit in FIG. 1(a). A LED chip 4 is deposited in the cavity and is connected to a pair of electrical terminals 7 on the PCB 1. According to the illustrated embodiment shown in FIG. 2(b), a first electrical contact at the bottom of the LED chip 4 can be electrically connected and secured to a first electrical terminal of a pair of electrical terminals 7 by an adhesive conductive material, and a second electrical contact at the top of the LED chip 4 can be electrically connected to a second electrical terminal of the pair of electrical terminals 7 by an electrical wire 5. The electrical wire 5 may be made of gold or any other suitable material. Since the LED chips 4 are directly mounted on the PCB 1, heat generated from the LED chips 4 can easily be dispersed through the PCB 1.

The LED chip 4 can be a low-power chip (below 0.1 W per chip), or a medium power chip (0.1-0.5 W per chip), or a high-power chip (over 0.5 W per chip). The LED chips 4 can produce different colors. Depending on the visual effect to be achieved, the LED lighting unit may contain a plurality of LED chips 4 of the same color, or a plurality of LED chips 4 of different colors. The colors emitting from the LED chips 4 can be any visible lights with a peak wavelength kp ranging from 430 nm to 700 nm, and blending white light. The luminous efficacy of the LED chips 4 can be more than 15 Lm/w. The LED chips 4 can be suitable for operation in a wide range of temperatures ranging from −40° C. to 70° C. The life span of the LED chips 4 can be up to ten years, which is tens times more than that of the existing incandescent lamps and fluorescent lamps.

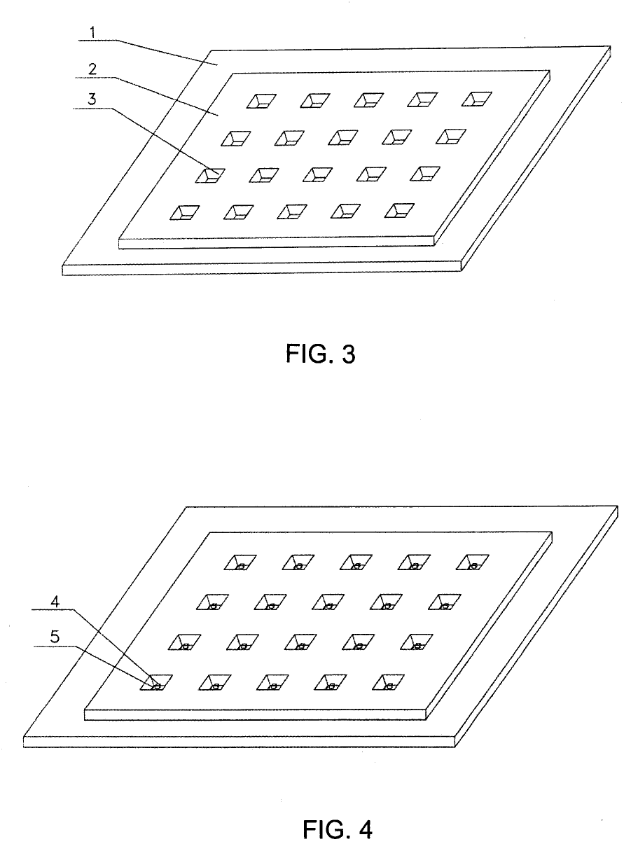

FIG. 1(c) is a cross sectional view of a cavity of the LED lighting unit taken along the line A-A in FIG. 1(a). It can be seen that each cavity has an outwardly diverging wall in generally truncated conical shape to facilitate the emission and reflection of light from the LED chip 4. The outwardly diverging wall in cross section may have an angle between 0° and 180° with respect to the upper surface of the PCB 1. A method of manufacturing the LED lighting unit is described hereinbelow with reference to FIGS. 3-5. FIG. 3 shows the casing 2 integrally formed on the printed circuit board 1 by injection molding. The PCB 1 has pairs of electrical terminals 7 formed thereon. The casing 2 may be in the form of a panel overlaying one side of the PCB 1. The overlaying panel has an array of opening 3 which defines an array of cavities. Each opening 3 aligns with and exposes one pair of electrical terminals 7 on the PCB 1. FIG. 4 shows LED chips 4 deposited in the cavities and connected to the electrical terminals 7 by electrical wires 5.

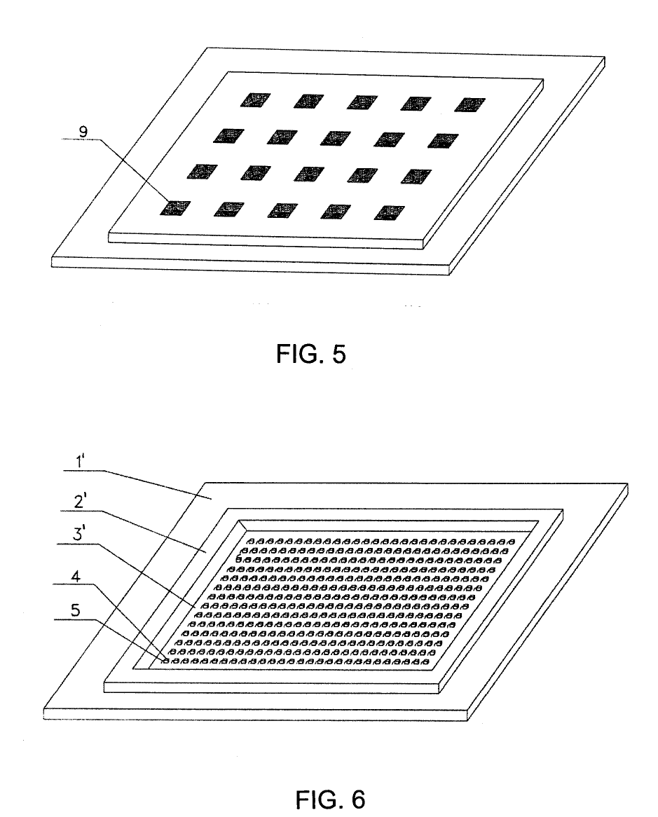

FIG. 5 shows seals 9 formed in the cavities encapsulating the LED chips 4 deposited therein. The seals 9 serve to bond the electrical wires 4 and protect the LED chips 4 from contamination such as dust. The seal 9 may be made of curable epoxy resin or any light transmissible sealing material that allows transmission of light from the LED chips 4. The seals 9 may be transparent or may comprise yellow fluorescent particles, or fluorescent particles of any colors to produce any desired color effects.

FIG. 6 is a perspective view of a LED lighting unit according to another embodiment disclosed in the present application. According to this embodiment, the casing 2′ is in the form of a rectangle having only one opening 3′ that exposes all the pairs of electrical terminals 7 on the PCB 1′.

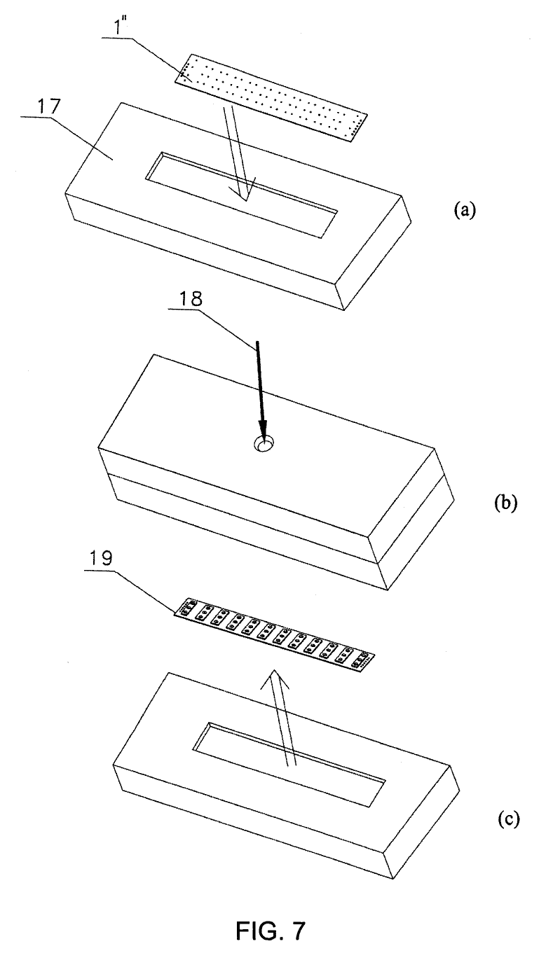

FIGS. 7(a)-7(c) show the injection molding process of the LED lighting unit. The injection molding process of the LED light unit can be carried out by a conventional injection molding machine. FIG. 7(a) illustrates the process of placing a printed circuit board 1″ in a cavity of a lower mold 17. According to the illustrated embodiment, the printed circuit board 1″ is rectangular in shape. A pattern of electrical conductors is formed on the printed circuit board 1″ on one side thereof. The pattern of electrical conductors includes pairs of electrical terminals for subsequent connection with LED chips. The printed circuit board 1″ is placed in the cavity of the lower mold 17 such that the pairs of electrical terminals are facing upwards. FIG. 7(b) illustrates the process of lowering an upper mold onto the lower mold and injecting molding material into the closed molds in a conventional manner as shown by arrow 18. FIG. 7(c) illustrates the process of removing the integrally formed unit 19 from the lower mold cavity after injection molding is completed.

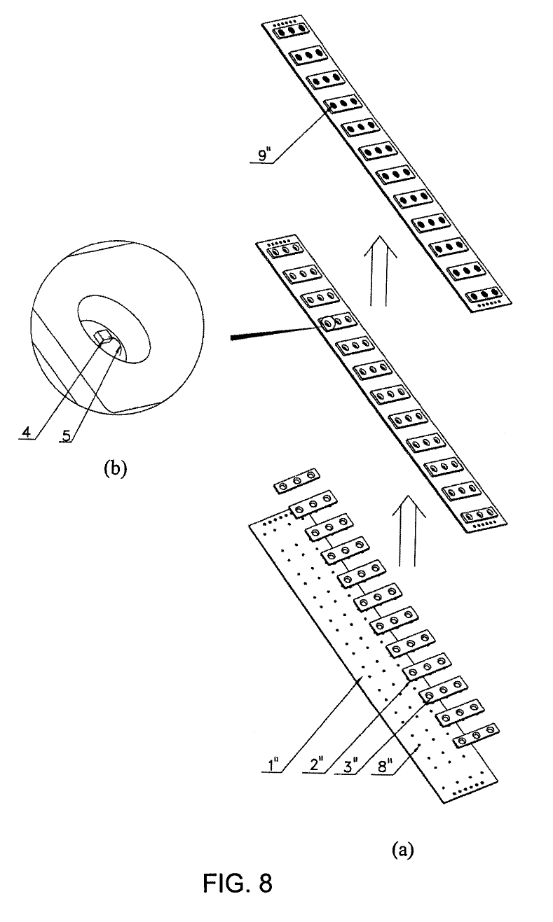

FIG. 8(a) illustrates an embodiment of the LED lighting unit. According to this embodiment, the casing 2″ is in the form of a plurality of overlaying panels each having a plurality of openings 3″ formed thereon. Each opening 3″ aligns with and exposes a pair of electrical terminals 7 on the PCB 1″. The plurality of openings 3″ defines a plurality of cavities for receiving therein the LED chips 4. The plurality of casing 2″ may be formed on the PCB 1″ by injection molding, as illustrated in FIGS. 7(a)-(c). LED chips 4 are deposited in the cavities and are connected to the PCB 1″ by electrical wires 5, as depicted in FIG. 8(b). Seals 9″ can be formed in the cavities covering the LED chips 4 deposited therein. The PCB 1″ may further be provided with a plurality of apertures 8″ for receiving molding material of the casing 2″ during injection molding such that the casing 2″ can be firmly integrated with the PCB 1″.

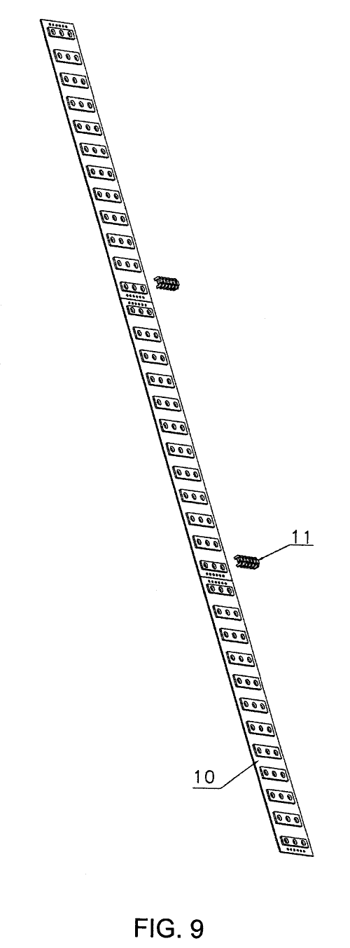

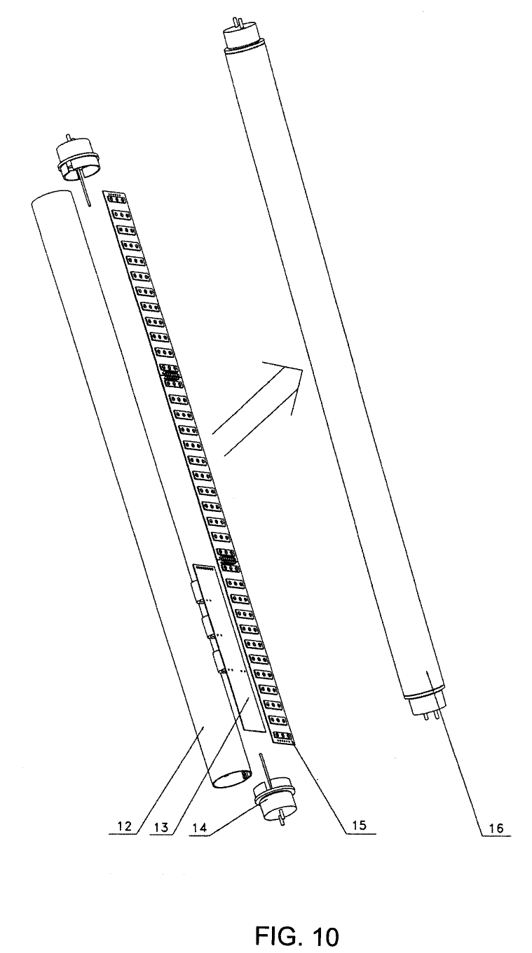

FIG. 9 illustrates the end-to-end connection of three LED lighting units 10 by two conductive connectors 11. FIG. 10 depicts the assembling of a lighting device using the LED lighting units in FIG. 9. The lighting device may include an elongated tube 12 for receiving therein a connected LED lighting unit 15 and a power source 13. A pair of electrode plug heads 14 may be secured to the two opposite ends of the elongated tube 12 respectively. A fluorescent tube-like LED lighting device 16 is then formed. The fluorescent tube-like LED lighting device 16 can be suitable for fitting in electrical sockets of conventional fluorescent tube brackets. The fluorescent tube-like LED lighting device 16 can replace conventional fluorescent tubes which are much shorter in lifespan and produce less brightness as compared to the LED lighting device disclosed in the present application.

The manufacturing of the light emitting diode (LED) lighting device of the present patent application generally can be summarized into the steps of: (i) providing a printed circuit board (PCB); (ii) integrally forming a casing on the PCB by injection molding; (iii) mounting LED chips onto the integrated PCB and casing; (iv) wiring the LED chips to the electrical terminals on the PCB; (v) encapsulating the LED chips by seals; and (vi) forming various lighting devices using one or more of the formed LED lighting units.

The LED lighting device of the present application can be uses indoors or outdoors, and can be used as the background light of LCD and advertisement light boards. The LED lighting device of the present application is easy to manufacture, low in manufacturing cost, and high in heat dissipation capacity.

Although it has been described that the LED chips 4 are connected to the pairs of electrical terminals 7 formed on one side of the printed circuit board 1, it is understood by one skilled in the art that the LED chips 4 can be connected to pairs of electrical terminals that may be formed on the other side of the printed circuit board 1 so that light can be emitting from both sides of the printed circuit board 1. It can also be understood that two printed circuit boards 1 can be mounted back-to-back to produce the same effect. Finally, it is understood that the LED light units disclosed in the present application can be of any size and shape and can be connected together in any possible ways to produce the desired structures, designs and visual effects of the final lighting products.

While the LED lighting device and method disclosed in the present application have been shown and described with particular references to a number of preferred embodiments thereof, it should be noted that various other changes or modifications may be made without departing from the scope of the present invention.

What is claimed is:

1. A method of manufacturing a light emitting diode (LED) lighting unit comprising the steps of:
providing a printed circuit board with pairs of electrical terminals formed on one side thereof;
integrally forming a casing on the one side of the printed circuit board by injection molding while exposing the pairs of electrical terminals;
providing a plurality of LED chips; and
electrically connecting each of the LED chips to each pair of electrical terminals.

2. The method as claimed in claim 1, wherein the printed circuit board is provided with a plurality of apertures for receiving molding material of the casing during injection molding.

3. The method as claimed in claim 1, wherein the casing is in the form of an overlaying panel comprising a plurality of openings each exposing one pair of the pairs of electrical terminals, and defining a plurality of cavities for receiving the LED chips.

4. The method as claimed in claim 3, further comprising filling each cavity with a light transmissible sealing material that encapsulates each LED chip in each cavity after the step of electrically connecting each of the LED chips to each pair of electrical terminals.

5. The method as claimed in claim 1, wherein the step of electrically connecting each of the LED chips to each pair of electrical terminals comprises connecting first and second electrical contacts of each of the LED chips to first and second electrical terminals of a corresponding pair of electrical terminals, respectively.

6. The method as claimed in claim 5, wherein the first electrical contact is connected to the first electrical terminal by an electrical wire.

7. The method as claimed in claim 5, wherein the second electrical contact is connected to the second electrical terminal by an adhesive conductive material.

8. The method as claimed in claim 1, wherein the casing is in the form of an overlaying panel comprising one opening that exposes the pairs of electrical terminals on the printed circuit board.

9. A light emitting diode (LED) lighting unit comprising:
a printed circuit board comprising pairs of electrical terminals formed on one side thereof;
a casing integrally formed on the one side of the printed circuit board by injection molding; and
a plurality of LED chips, each of the LED chips being electrically connected to each pair of electrical terminals, and the LED chips being exposed in the casing.

10. The unit of claim 9, wherein the casing is in the form of an overlaying panel comprising a plurality of openings each exposing one pair of the electrical terminals, and defining a plurality of cavities for receiving the LED chips.

11. The unit of claim 10, further comprising a light transmissible sealing material filled in each cavity encapsulating each of the LED chips in each of the cavities.

12. The unit of claim 10, wherein each cavity has an outwardly diverging wall in generally truncated conical shape to facilitate LED light emission, and the outwardly diverging wall in cross section has an angle between 0° and 180° with respect to a surface of the one side of the printed circuit board.

13. The unit of claim 9, wherein the casing is in the form of an overlaying panel comprising one opening that exposes the pairs of electrical terminals on the printed circuit board.

14. The unit of claim 9, wherein first and second electrical contacts of each of the LED chips are connected to first and second electrical terminals of a corresponding pair of electrical terminals, respectively.

15. The unit of claim 14, wherein the first electrical contact is connected to the first electrical terminal by an electrical wire.

16. The unit of claim 14, wherein the second electrical contact is connected to the second electrical terminal by an adhesive conductive material.

17. The unit of claim 9, wherein the printed circuit board is provided with a plurality of apertures for receiving molding material of the casing during injection molding.

18. A lighting device comprising one or more light emitting diode (LED) lighting units, each of the units comprising:
a printed circuit board comprising pairs of electrical terminals formed on one side thereof;
a casing integrally formed on the one side of the printed circuit board by injection molding, wherein the printed circuit board is provided with a plurality of apertures for receiving molding material of the casing during injection molding;
a plurality of LED chips, each of the LED chips being electrically connected to each pair of electrical terminals, the LED chips being exposed in the casing, wherein the casing is in the form of an overlaying panel comprising a plurality of openings each exposing one pair of the electrical terminals, and defining a plurality of cavities for receiving the LED chips; and
a light transmissible sealing material filled in each cavity encapsulating each of the LED chips in each of the cavities.

19. The lighting device of claim 18, further comprising one or more conductive connectors connecting the LED lighting units in an end-to-end configuration if there are two or more LED lighting units.

20. The lighting device of claim 18, further comprising an elongated tube for receiving therein the LED lighting units, and a pair of electrode plug heads secured to two opposite ends of the elongated tube.
